(19) United States
(12) Patent Application Publication
(10) Pub. No.: US 2026/0098875 A1
(43) Pub. Date: Apr. 9, 2026

(54) CANTILEVER-TYPE PROBE FOR PROBE CARD, AND PROBE CARD

(71) Applicant: JAPAN ELECTRONIC MATERIALS CORPORATION, Amagasaki, Hyogo (JP)

(72) Inventor: Shohei TAJIMA, Amagasaki-shi, Hyogo (JP)

(73) Assignee: JAPAN ELECTRONIC MATERIALS CORPORATION, Amagasaki, Hyogo (JP)

(21) Appl. No.: 19/112,737

(22) PCT Filed: Sep. 21, 2022
(86) PCT No.: PCT/JP2022/035191

§ 371 Date: Mar. 18, 2025

(51) Int. Cl. G01R 1/067

(52) U.S. Cl. CPC G01R 1/06727; G01R 1/0675; G01R 1/06761

(57) ABSTRACT

A cantilever-type probe for a probe card includes: a base part that extends upward from a terminal part connected to a wiring board; a needle tip part; and a beam part positioned between the base part and the needle tip part. The base part includes multiple three-dimensional stress distribution sections, such as recesses or protrusions, arranged along the longitudinal direction of the terminal part.

### TECHNICAL FIELD

The present disclosure relates to a cantilever-type probe for a probe card, and a probe card.

### BACKGROUND ART

A probe card is an electrical connection device used to conduct operational tests on individual semiconductor devices formed on a wafer. The probe enables the supply of power; input and output of signals; and grounding by bringing the probe into contact with the electrode pads of the semiconductor devices.

Probes are installed on the surface of the probe card and are configured to press their tips against the electrode pads of the semiconductor devices with a predetermined pressing force.

To increase the number of semiconductor devices formed on a wafer, it is necessary to reduce the size of the semiconductor devices. Consequently, the electrode pads of semiconductor devices are designed to be smaller, and the distance (pitch) between the electrode pads is also reduced. Therefore, it becomes necessary to finely structure the probes in accordance with the miniaturization of semiconductor devices. However, miniaturizing the probes results in a problem of reduced mechanical strength when soldering the terminal part to the land provided on a probe circuit board.

To solve this problem, a probe has been proposed with a structure where a through-hole is formed near the end face of the connection section of the probe body to the land, allowing molten solder to pass through this part and be guided to the opposite side (e.g., see Patent Document 1).

### Citation List

### Patent Document

Japanese Patent No. 5060965

### SUMMARY OF THE INVENTION

### Problem to Be Solved by the Invention

When soldering the probe to the land on the probe circuit board, stress occurs around the joint section near the base of the probe due to the shrinkage of the solder as it solidifies. In cases where a through-hole is provided at the end of the probe, although the adhesion strength is enhanced, there is a problem where stress becomes excessively concentrated around the hole.

The present disclosure has been made to solve the aforementioned problems and the object of the present disclosure is to provide a cantilever-type probe for a probe card and a probe card that can maintain sufficient adhesion strength during soldering to the land of the probe circuit board; even when the probe is miniaturized; and effectively distribute the stress generated at the base of the probe during solder shrinkage.

### Means to Solve the Problem

The cantilever-type probe for a probe card disclosed in this disclosure includes: a base part that extends upward from a terminal part connected to a wiring board; a needle tip part; and a beam part positioned between the base part and the needle tip part. The base part includes a plurality of three-dimensional stress distribution sections, which are non-through recesses in the base part in the thickness direction of the base part [0029, FIG. 2B, FIG. 3] or protrusions, arranged along the longitudinal direction of the terminal part, and spaced apart from an end face on the wiring board side [0019, FIG. 1, FIG. 2A, FIG. 3].

Furthermore, a probe card disclosed in this disclosure includes: a cantilever-type probe for a probe card, which includes a base part that extends upward from a terminal part connected to a wiring board, a needle tip part, and a beam part positioned between the base part and the needle tip part; and a wiring board. The base part includes a plurality of three-dimensional stress distribution sections, which are non-through recesses in the base part in the thickness direction of the base part [0029, FIG. 2B, FIG. 3], arranged along the longitudinal direction of the terminal part, and spaced apart from an end face on the wiring board side [0019, FIG. 1, FIG. 2A, FIG. 3], in a solder layer that fixes the probe to a land of the wiring board, solder parts formed in the recesses are fixed to an end-face joint section formed between the land and the terminal part, by the solder layer covering side surfaces of the base part in a cantilever-like structure.

### Effect Of the Invention

According to the cantilever-type probe and the probe card disclosed in the present disclosure; even when the probe is miniaturized; it is possible to provide a probe for a probe card that maintains sufficient adhesion strength during soldering to the land of the probe circuit; and effectively distributes the stress generated at the base part of the probe during solder shrinkage.

### BRIEF DESCRIPTION OF THE DRAWINGS

FIG. 1 is a perspective view of a cantilever-type probe for a probe card according to Embodiment 1.

FIG. 2A is a plan view of the portion enclosed by the dashed line in FIG. 1.

FIG. 2B is a cross-sectional view along line A-A in FIG. 2A.

FIG. 3 is a cross-sectional view showing the vicinity of the terminal part of a probe soldered to the land of the wiring board, taken perpendicularly to the longitudinal direction Z at the recessed portion, according to Embodiment 1.

FIG. 4 is a cross-sectional view showing the state where the sacrificial layer is placed to form the recess in the portion enclosed by the dashed line in FIG. 1.

FIG. 5 is a perspective view of a cantilever-type probe for a probe card according to Embodiment 2.

FIG. 6 is a plan view of the portion enclosed by the dashed line in FIG. 5.

FIG. 7 is a cross-sectional view showing the vicinity of the terminal part of a probe soldered to the land of the wiring board, taken perpendicularly to the longitudinal direction Z at the recessed portion.

FIG. 8A is a partial plan view of a modified example of the recesses in a probe according to Embodiment 3.

FIG. 8B is a cross-sectional view along line F-F in FIG. 8A.

FIG. 9A is a partial plan view of modified example of the recesses in a probe according to Embodiment 4.

FIG. 9B is a cross-sectional view along line G-G in FIG. 9A.

FIG. 10 is a diagram showing a method of manufacturing the probe by pressing according to Embodiment 4.

FIG. 11A is a partial plan view of the protrusion in a probe according to Embodiment 5.

FIG. 11B is a cross-sectional view along line M-M in FIG. 11A.

### DESCRIPTION OF EMBODIMENTS

### Embodiment 1

Herein after, a cantilever-type probe for a probe card and a probe card according to Embodiment 1 will be described below with reference to the drawings.

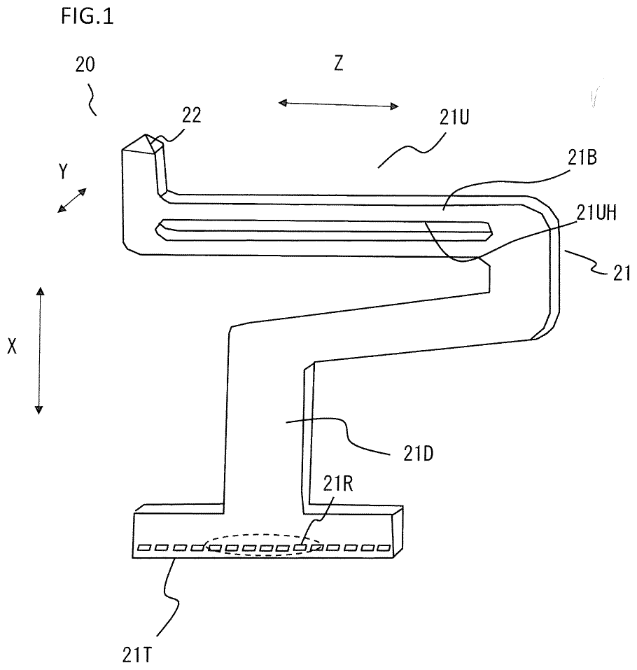

FIG. 1 is a perspective view of a cantilever-type probe 20 for a probe card (hereinafter simply referred to as the probe 20) according to Embodiment 1. It shows a perspective view of the probe before being mounted to the wiring board of a probe card (not shown).

In this specification, the upper side of the sheet of FIG. 1 is referred to as “up,” and the lower side is referred to as “down.” The direction in which the probe 20 undergoes buckling (elastic deformation) during overdrive is referred to as the buckling direction X. The direction orthogonal to the buckling direction X, which corresponds to the thickness direction of the probe 20 during its manufacturing process when metal films are laminated, is referred to as the plate thickness direction Y. The longitudinal direction of the terminal part 21T of the probe 20 is referred to as the longitudinal direction Z.

The probe 20 is a component used in a probe card (not shown). A probe card is a device used to inspect the electrical characteristics of electronic circuits formed on a semiconductor wafer. The inspection of the characteristics of electronic circuits is performed by bringing the semiconductor wafer close to the probe card, contacting the tip of the probe 20 with the electrodes on the electronic circuits, and establishing conductivity between the tester device and the tester connection electrodes of the wiring board on the probe card through the probe 20.

The probe 20 is a cantilever-type probe arranged so that the beam part 21B remains nearly horizontal relative to the target of inspection (electronic circuits formed on the semiconductor wafer).

The probe 20 comprises a thin plate-shaped main body 21 and a needle tip part 22 protruding upward from the upper end of the main body. The main body 21 includes a terminal part 21T, which is connected to a wiring land of a wiring board (not shown) located below in FIG. 1; a base part 21D rising upward from the terminal part 21T; and an elastic deformation portion 21U positioned between the terminal part 21T and the base part 21D.

The elastic deformation portion 21U has a single elongated hole 21UH extending in the longitudinal direction Z and penetrating in the plate thickness direction Y. The elongated hole 21UH divides the elastic deformation portion 21U into two beam parts 21B. Although FIG. 1 shows an example with two beam parts 21B, the number of beam parts 21B may be one or more than three.

During overdrive, the probe 20 undergoes buckling deformation in the buckling direction X according to the reaction force from the target of inspection when compressive force is applied in the vertical direction of FIG. 1.

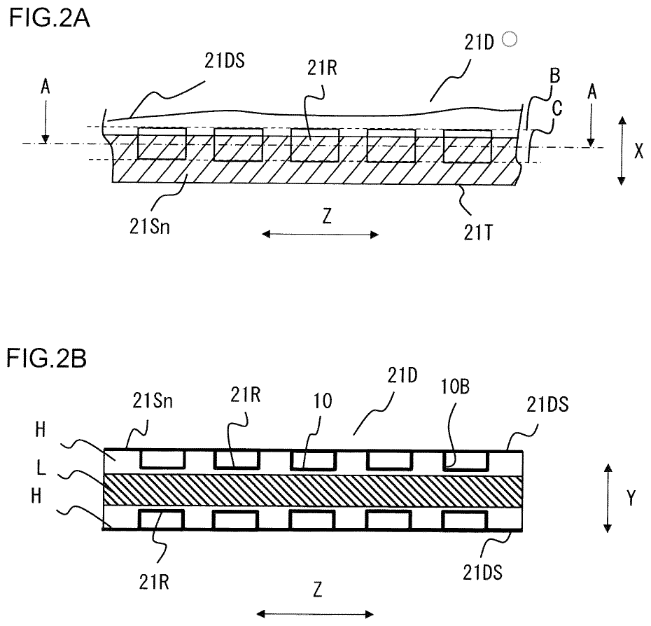

FIG. 2A is a plan view of the portion enclosed by the dashed line in FIG. 1, showing the vicinity of the terminal part 21T side of the base part 21D as viewed in the plate thickness direction Y of the probe 20. FIG. 2B is a cross-sectional view along line A-A in FIG. 2A.

The probe 20 comprises two types of metals with different resistivities. One is an inner metal (first metal) forming the low-resistance portion L, made of low-resistance metals such as copper, gold, or silver (Cu, Au, Ag). The low-resistance portion L functions to improve conductivity and current-carrying performance. The other is an outer metal (second metal) forming the high-resistance portion H, made of higher-resistance metals such as palladium-cobalt (PdCo) alloy. Although less conductive than the low-resistance portion L, the high-resistance portion H has higher mechanical strength and spring characteristics. The high-resistance portion H serves to maintain the mechanical strength of the probe 20.

As shown in FIGS. 1, 2A, and 2B, multiple rectangular prism-shaped recesses 21R are arranged in a single row along the longitudinal direction Z, on both surfaces 21DS of the base part 21D in the plate thickness direction Y, near the terminal part 21T of the probe 20. Furthermore, a tin alloy layer 21Sn is formed covering the entire terminal part 21T side of the base part 21D, from a position closer to the terminal part 21T than the line segment B connecting the upper ends of the recesses 21R, and higher than the line segment C connecting the lower ends shown in FIG. 2A. By melting this tin alloy layer 21Sn, the probe 20 is secured to the land of a wiring board. By melting this tin alloy layer 21Sn, the probe 20 is fixed to the land of the wiring board.

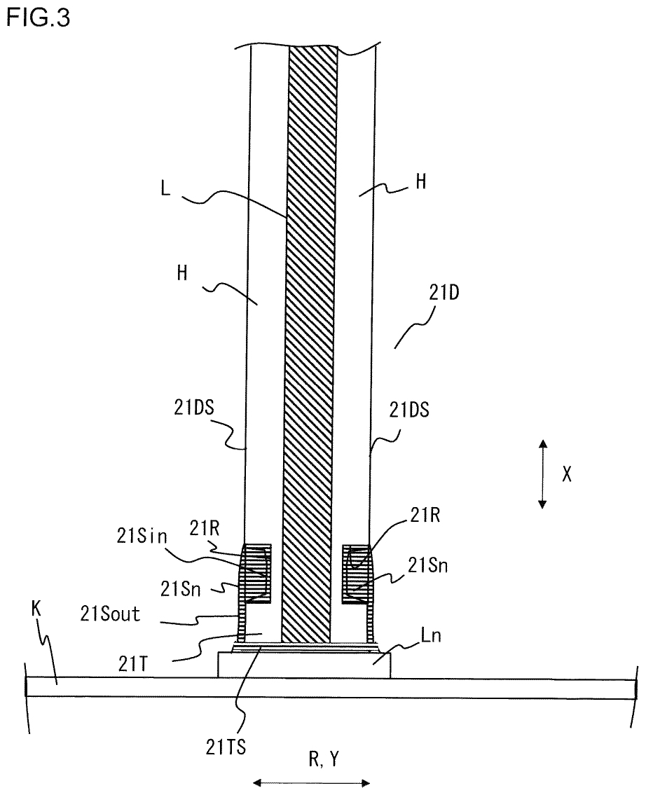

FIG. 3 is a cross-sectional view of the vicinity of the terminal part 21T of the probe 20 soldered to the land Ln of the wiring board K, taken perpendicularly to the longitudinal direction Z at the recess 21R. When the terminal part 21T of the probe 20 is pressed against the land Ln of the wiring board K and the tin alloy layer 21Sn is heated, the molten tin alloy adheres to the inner wall surface of the recess 21R and solidifies in a fillet shape together with the tin alloy layer 21Sn formed on other parts, including the end face of the terminal part 21T.

The recesses 21R are formed in the high-resistance portion H. Finite element method (FEM) analysis of the stress after soldering shows that the stress of the solidifying solder concentrates on the vertices 10B of the recesses 21R and the ridges 10 formed by adjacent surfaces of the recesses 21R shown in FIG. 2B.

As described above, by arranging rectangular prism-shaped recesses 21R as stress distribution sections uniformly along the longitudinal direction Z on the base part 21D of the probe 20, the stress occurring on the fixed portion due to soldering can be evenly distributed to the vertices 10B and ridges 10 of the recesses 21R.

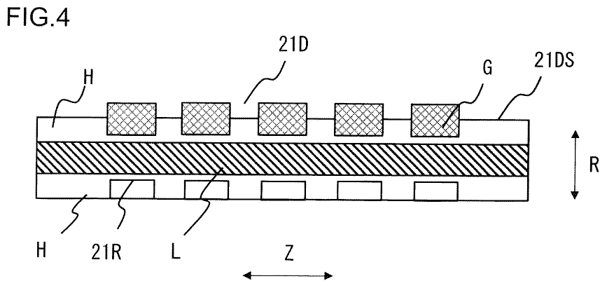

FIG. 4 is a cross-sectional view showing the state where the sacrificial layer G is placed to form the recesses 21R in the portion enclosed by the dashed line in FIG. 1. The stacking direction R indicates the direction in which the metal layers are laminated during manufacturing.

The probe 20 is manufactured using the so-called MEMS (Micro Electro Mechanical Systems) technology. MEMS technology enables the creation of fine three-dimensional structures using photolithography and sacrificial layer etching. Photolithography is a micro-patterning technology that utilizes photoresists, commonly used in semiconductor manufacturing processes. Sacrificial layer etching creates three-dimensional structures by forming a sacrificial layer G, constructing structural layers on top of it, and then selectively removing the sacrificial layer G through etching.

To form the high-resistance portion H and the low-resistance portion L, well-known plating technology can be used. For example, immersing a substrate as a cathode and a metal piece as an anode into electrolyte solution, and applying voltage between the electrodes, deposits metal ions in the electrolyte solution onto the substrate surface. This process, known as electroplating, is a wet process that requires drying after plating. Following the drying process, the needle tip part 22 undergoes polishing through grinding process.

Specifically, the lower high-resistance portion H shown in FIG. 2B is first formed, excluding the areas corresponding to the recesses 21R. Subsequently, the upper high-resistance portion H, positioned above the lower recesses 21R and below the low-resistance portion L, is formed. Then, the low-resistance portion L is formed. Furthermore, the high-resistance portion H above the low-resistance portion L and below the lower surface of the upper recesses 21R, as shown in FIG. 2B, is formed. Finally, the upper high-resistance portion H, excluding the upper recesses 21R in FIG. 2B, is formed.

A tin alloy layer 21Sn is then formed by immersing the terminal part 21T into molten tin alloy over the specified range described above. As multiple recesses 21R are formed in the longitudinal direction Z of the base part 21D near the terminal part 21T, the tin alloy layer 21Sn is prevented from spreading beyond the recesses 21R. Alternatively, the tin alloy layer 21Sn can be formed by plating while masking the outer periphery except for the areas where the tin alloy layer 21Sn is to be formed.

Subsequently, the terminal part 21T of the probe 20, with the tin alloy layer 21Sn formed, is pressed against the land Ln of the wiring board K. Heat is applied to melt the tin alloy layer 21Sn, thereby soldering the probe 20 to the land Ln.

As shown in FIG. 3, the molten tin alloy layer 21Sn (solder) follows to the inner wall surface of the recesses 21R and solidifies. The solder does not extend beyond the upper surface of recesses 21R to the upper part of base part 21D. As shown in FIG. 3, the cross-sectional shape of the solidified tin alloy layer 21Sn clamps the terminal part 21T in the vertical direction. Because recesses 21R do not penetrate through the recesses 21R in the stacking direction R of the probe 20, excessive stress is not applied to the terminal part 21T due to shrinkage during solder solidification. Additionally, stress is distributed across multiple recesses 21R, ensuring a stable bond for the probe 20.

Although this embodiment explained an example in which two types of metals are used, the high-resistance portion H and the low-resistance portion L, it is also possible to manufacture the probe 20 using a single type of metal.

According to the cantilever-type probe for a probe card and the probe card of Embodiment 1, the stress generated inside the probe 20 during soldering to the land Ln of the wiring board K can be evenly distributed to the vertices 10B and ridges 10 of the recesses 21R. This makes it possible to provide a cantilever-type probe for a probe card with high mechanical strength.

Additionally, since the recesses 21R can prevent solder from climbing up during bonding, it is possible to provide the cantilever-type probe for a probe card and the probe card with consistent bonding quality.

Furthermore, since the recesses 21R can accommodate excess solder, it is possible to prevent the fillet shape from spreading excessively sideways.

Moreover, In the solder layer after fixing, solder parts 21Sin formed in the recesses 21R are fixed to the end-face joint section 21TS as an adhesive layer of solder, formed between the land Ln and the terminal part 21T, by the solder layer 21Sout covering the side surfaces of the base part 21D in a cantilever-like structure. As a result, it enhances flexibility, durability, and resistance to peeling.

### Embodiment 2

A cantilever-type probe for a probe card and a probe card according to Embodiment 2 will be described below, focusing on parts different from Embodiment 1.

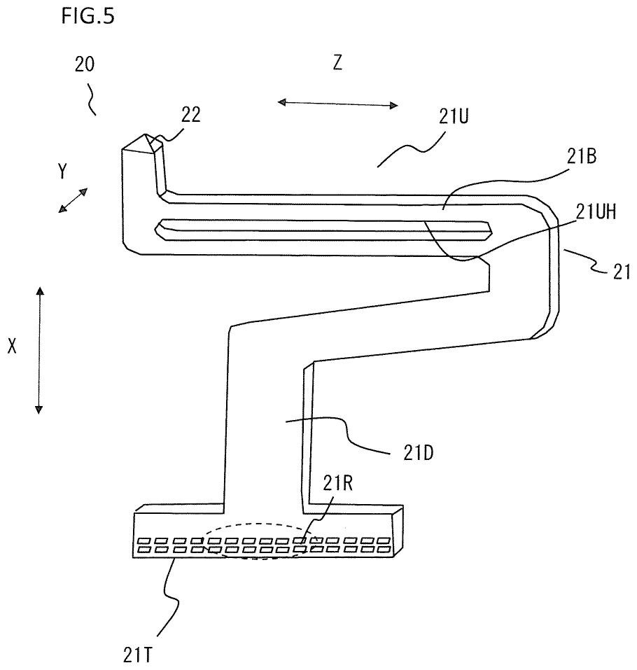

FIG. 5 is a perspective view of a cantilever-type probe 20 for a probe card (hereinafter simply referred to as the probe 20) according to Embodiment 2. It shows a perspective view of the probe before being mounted to the wiring board K of a probe card (not shown).

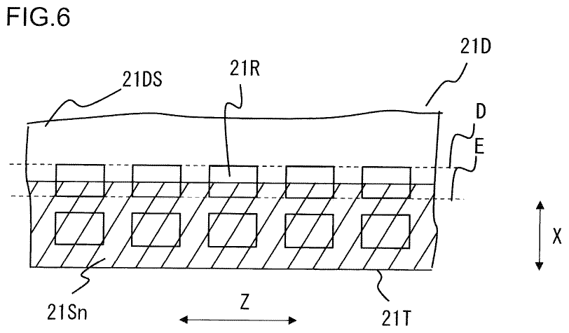

FIG. 6 is a plan view of the portion enclosed by the dashed line in FIG. 5, showing the vicinity of the terminal part 21T side of the base part 21D as viewed in the plate thickness direction Y of the probe 20.

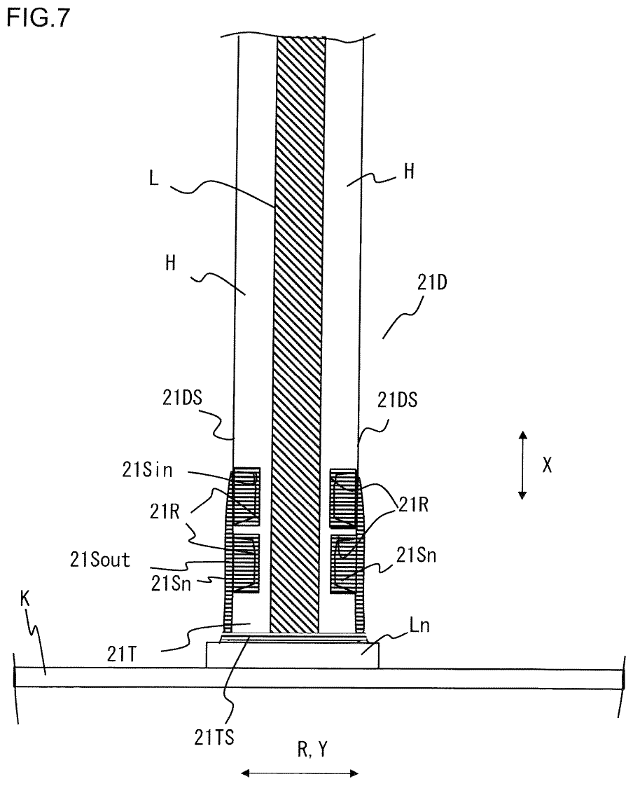

FIG. 7 is a cross-sectional view of the vicinity of the terminal part 21T of the probe 20 soldered to the land Ln of the wiring board K, taken perpendicularly to the longitudinal direction Z at the recesses 21R.

In Embodiment 1, an example was shown where multiple rectangular prism-shaped recesses 21R are provided in a single row along the longitudinal direction Z on both surfaces 21DS in the plate thickness direction Y of the base part 21D, near the terminal part 21T of the probe 20. In this embodiment, the recesses 21R are provided in two rows along the longitudinal direction Z. Additionally, in Embodiment 2, the area where the tin alloy layer 21Sn is formed is the region from, between line D and line E, to the terminal part 21T side in FIG. 6. Line D is a line connecting the upper ends of the recesses 21R in the row on the needle tip part 22 side, and line E connects the lower ends of the same row on the terminal part 21T side.

When multiple rows of recesses 21R are provided along the longitudinal direction Z, forming the tin alloy layer 21Sn so that it covers at least part of the inside of the uppermost recesses 21R (on the needle tip part 22 side) achieves the same effects as in Embodiment 1.

### Embodiment 3

A cantilever-type probe for a probe card and a probe card according to Embodiment 3 will be described below, focusing on parts different from Embodiment 1.

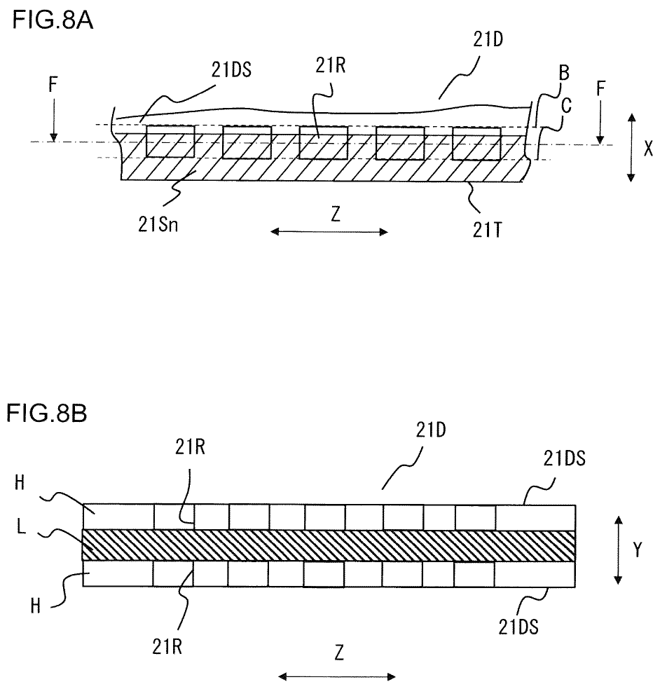

FIG. 8A is a plan view of a modified example of the recesses 21R of the probe 20. It shows the vicinity of the terminal part 21T side of the base part 21D as viewed in the plate thickness direction Y of the probe 20.

FIG. 8B is a cross-sectional view along line F-F in FIG. 8A.

In Embodiment 1, the recesses 21R did not penetrate through the high-resistance portion H in the direction perpendicular to the buckling direction X. In this embodiment, the recesses 21R penetrate through the high-resistance portion H in the direction perpendicular to the buckling direction X.

Even with this structure, the same effects as in Embodiment 1 are achieved. The depth of the recesses 21R can be adjusted to match the required mechanical strength. Additionally, recesses that penetrate only the high-resistance portion H may also be used. In this case, the manufacturing process for the probe 20 can be simplified.

### Embodiment 4

A cantilever-type probe for a probe card and a probe card according to Embodiment 4 will be described below, focusing on parts different from Embodiment 1.

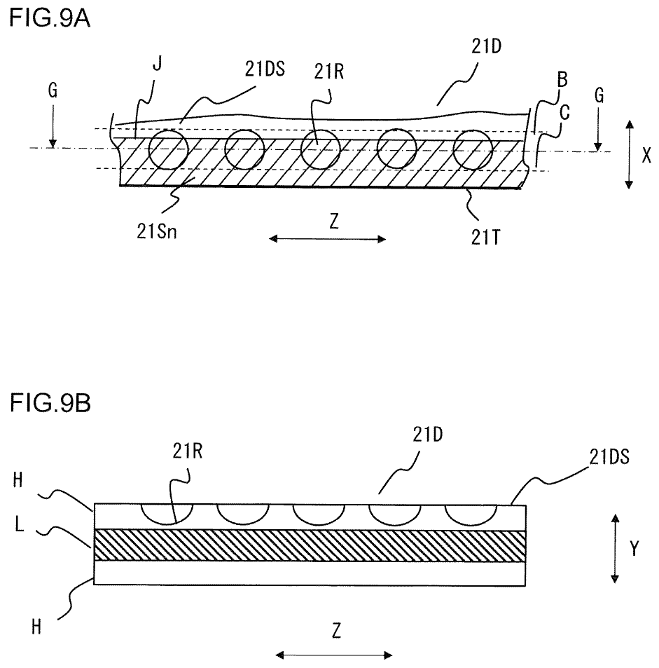

FIG. 9A is a plan view of a modified example of the recesses 21R of the probe 20, showing the vicinity of the terminal part 21T side of the base part 21D as viewed in the plate thickness direction Y of the probe 20.

FIG. 9B is a cross-sectional view along line G-G in FIG. 9A.

So far, examples where rectangular prism-shaped recesses 21R are provided near the terminal part 21T side of the base part 21D have been described. However, the recesses 21R may also have a dimple shape, that is, a hemispherical shape. This shape cannot be formed through metal layer lamination and requires pressing for formation.

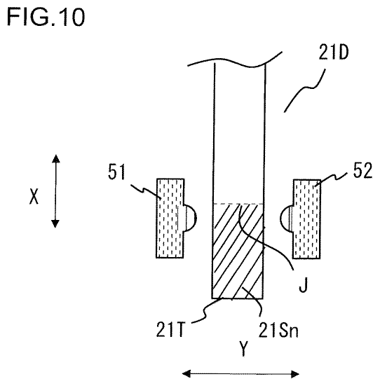

FIG. 10 shows the process of manufacturing the probe 20 using pressing.

The probe 20, made of laminated high-resistance portions H and low-resistance portion L, is pressed from both sides by a first mold 51 and a second mold 52, each having hemispherical protrusions corresponding to the respective recesses 21R, to form hemispherical recesses 21R on its surface.

In this case, compared to forming metal layers by electroplating, the manufacturing time can be shortened. Additionally, the recesses 21R may take various shapes, such as polygonal prisms, truncated polygonal pyramids, cylinders, or truncated cones. These shapes can also be manufactured through pressing. After forming the recesses 21R, a tin alloy layer 21Sn is applied to the specified range (in FIG. 10, the area on the terminal part 21T side of line J).

The cantilever-type probe for a probe card and the probe card according to Embodiment 4 achieve the same effects as in Embodiment 1.

### Embodiment 5

A cantilever-type probe for a probe card and a probe card according to Embodiment 5 will be described below, focusing on parts different from Embodiment 1.

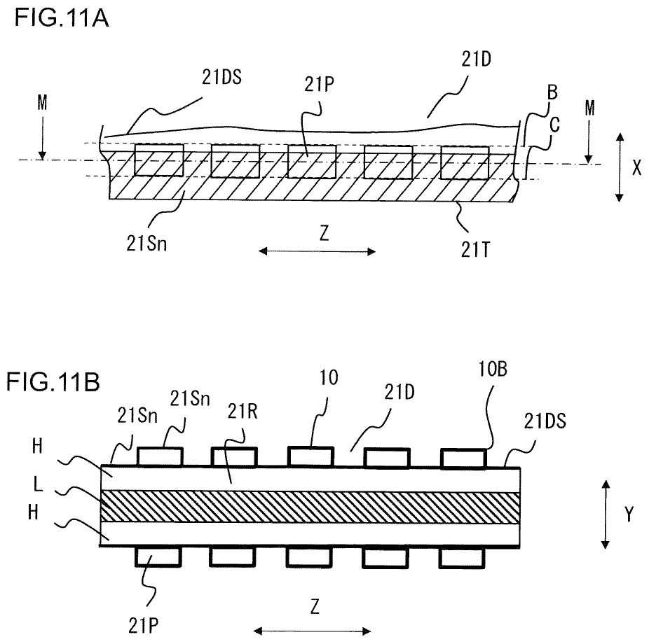

FIG. 11A is a plan view of a modified example of protrusions 21P as the stress distribution sections of the probe 20. FIG. 11A shows the vicinity of the terminal part 21T side of the base part 21D as viewed in the plate thickness direction Y of the probe 20.

FIG. 11B is a cross-sectional view along line M-M in FIG. 11A.

So far, the recesses 21R as stress distribution sections have been described. However, as shown in FIGS. 11A and 11B, the stress distribution sections may also be formed as protrusions 21P.

The cantilever-type probe for a probe card and the probe card according to Embodiment 5 achieve the same effects as in Embodiment 1.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications that have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### Description of the Reference Characters

20 cantilever-type probe for a probe card
10 ridge
10B vertex
21 main body
21B beam part
21D base part
21DS surface
21R recess
21Sn tin alloy layer
21Sout solder layer
21T terminal part
21TS end-face joint section
21U elastic deformation portion
21UH elongated hole
22 needle tip part
21P protrusion
51 first mold
52 second mold
G sacrificial layer
H high-resistance portion
L low-resistance portion
Ln land
R stacking direction
X buckling direction
Y plate thickness direction
Z longitudinal direction
K wiring board

1. A cantilever-type probe for a probe card, comprising:
a base part that extends upward from a terminal part connected to a wiring board;
a needle tip part; and
a beam part positioned between the base part and the needle tip part, wherein the base part includes a plurality of three-dimensional stress distribution sections, which are non-through recesses in the base part in the thickness direction of the base part or protrusions, arranged along the longitudinal direction of the terminal part, and spaced apart from an end face on the wiring board side.

2. The cantilever-type probe for a probe card according to claim 1, wherein
the stress distribution sections are arranged in a single row along the longitudinal direction of the base part.

3. The cantilever-type probe for a probe card according to claim 1, wherein
the stress distribution sections are arranged in multiple rows along the longitudinal direction of the base part.

4. The cantilever-type probe for a probe card according to claim 1, wherein
the stress distribution sections have any of the following shapes: polygonal prisms, truncated polygonal pyramids, cylindrical shapes, hemispherical shapes, or truncated cone shapes.

5. The cantilever-type probe for a probe card according to claim 1, further comprising:
a low-resistance portion made of a metal layer with low electrical resistance, and
a high-resistance portion, which are provided outsides of the low-resistance portion, having higher electrical resistance than the low-resistance portion, and having spring characteristics, wherein
the stress distribution sections are formed in the high-resistance portion.

6. The cantilever-type probe for a probe card according to claim 5, wherein
the stress distribution sections are recesses that penetrate through the high-resistance portion in the thickness direction of the base part.

7. A probe card, comprising:
a cantilever-type probe for a probe card, which includes a base part that extends upward from a terminal part connected to a wiring board, a needle tip part, and a beam part positioned between the base part and the needle tip part; and
a wiring board, wherein
the base part includes a plurality of three-dimensional stress distribution sections, which are non-through recesses in the base part in the thickness direction of the base part, arranged along the longitudinal direction of the terminal part, and spaced apart from an end face on the wiring board side,
in a solder layer that fixes the probe to a land of the wiring board, solder parts formed in the recesses are fixed to an end-face joint section formed between the land and the terminal part, by the solder layer covering side surfaces of the base part in a cantilever-like structure.

8. The cantilever-type probe for a probe card according to claim 2, further comprising:
a low-resistance portion made of a metal layer with low electrical resistance, and
a high-resistance portion, which are provided outsides of the low-resistance portion, having higher electrical resistance than the low-resistance portion, and having spring characteristics, wherein
the stress distribution sections are formed in the high-resistance portion.

9. The cantilever-type probe for a probe card according to claim 3, further comprising:
a low-resistance portion made of a metal layer with low electrical resistance, and
a high-resistance portion, which are provided outsides of the low-resistance portion, having higher electrical resistance than the low-resistance portion, and having spring characteristics, wherein
the stress distribution sections are formed in the high-resistance portion.

10. The cantilever-type probe for a probe card according to claim 4, further comprising:
a low-resistance portion made of a metal layer with low electrical resistance, and
a high-resistance portion, which are provided outsides of the low-resistance portion, having higher electrical resistance than the low-resistance portion, and having spring characteristics, wherein
the stress distribution sections are formed in the high-resistance portion.
